(19) United States
(12) Patent Application Publication
(10) Pub. No.: US 2024/0006526 A1
(43) Pub. Date: Jan. 4, 2024

(54) SEMICONDUCTOR DEVICE, METHOD FOR MANUFACTURING SEMICONDUCTOR DEVICE, AND ELECTRONIC DEVICE

(71) Applicant: Fujitsu Limited, Kawasaki-shi (JP)

(72) Inventor: Atsushi YAMADA, Hiratsuka (JP)

(73) Assignee: Fujitsu Limited, Kawasaki-shi (JP)

(21) Appl. No.: 18/190,304

(22) Filed: Mar. 27, 2023

(30) Foreign Application Priority Data
Jun. 30, 2022 (JP) 2022-106052

(51) Int. Cl. H01L 29/778; H01L 29/20; H01L 29/66

(52) U.S. Cl. CPC H01L 29/7787; H01L 29/2003; H01L 29/66462

(57) ABSTRACT

A semiconductor device includes: a channel layer that includes a first nitride semiconductor that contains Ga; a barrier layer that is provided on a first surface side of the channel layer, and includes a second nitride semiconductor that contains In, Al, and Ga; a source electrode and a drain electrode that are provided on a second surface side of the barrier layer opposite to the channel layer side; and a gate electrode that is provided between the source electrode and the drain electrode, on the second surface side of the barrier layer. An In composition of each of a first region of the barrier layer that faces the source electrode and a second region of the barrier layer that faces the drain electrode is smaller than an In composition of a third region between the first region and the second region of the barrier layer.

### CROSS-REFERENCE TO RELATED APPLICATION

This application is based upon and claims the benefit of priority of the prior Japanese Patent Application No. 2022-106052, filed on Jun. 30, 2022, the entire contents of which are incorporated herein by reference.

### FIELD

The embodiments discussed herein are related to a semiconductor device, a method for manufacturing the semiconductor device, and an electronic device.

### BACKGROUND

A semiconductor device including a nitride semiconductor is known. For example, a high electron mobility transistor (HEMT) including a channel layer (also referred to as a carrier transit layer, an electron transit layer, or the like) using gallium nitride (GaN) or the like and a barrier layer (also referred to as a carrier supply layer, an electron supply layer, or the like) using aluminum gallium nitride (AlGaN) or the like is known.

Japanese Laid-open Patent Publication No. 2016-178325, Japanese Laid-open Patent Publication No. 2018-64027, and U.S. Patent No. 2020/0220004 are disclosed as related art.

### SUMMARY

According to an aspect of the embodiments, a semiconductor device includes: a channel layer that includes a first nitride semiconductor that contains Ga; a barrier layer that is provided on a first surface side of the channel layer, and includes a second nitride semiconductor that contains In, Al, and Ga; a source electrode and a drain electrode that are provided on a second surface side of the barrier layer opposite to the channel layer side; and a gate electrode that is provided between the source electrode and the drain electrode, on the second surface side of the barrier layer. An In composition of each of a first region of the barrier layer that faces the source electrode and a second region of the barrier layer that faces the drain electrode is smaller than an In composition of a third region between the first region and the second region of the barrier layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 a diagram describing an example of a semiconductor device according to a first embodiment;

FIG. 2 is a diagram illustrating an example of a relationship between an Al composition and a current of a nitride semiconductor;

FIG. 3 is a diagram describing an example of a semiconductor device according to a second embodiment;

FIGS. 4A and 4B are diagrams (part 1) describing an example of a method for manufacturing the semiconductor device according to the second embodiment;

FIGS. 5A and 5B are diagrams (part 2) describing the example of the method for manufacturing the semiconductor device according to the second embodiment;

FIGS. 6A and 6B are diagrams (part 3) describing the example of the method for manufacturing the semiconductor device according to the second embodiment;

FIG. 7 is a diagram describing an example of a semiconductor device according to a third embodiment;

FIGS. 8A and 8B are diagrams (part 1) describing an example of a method for manufacturing the semiconductor device according to the third embodiment;

FIGS. 9A and 9B are diagrams (part 2) describing the example of the method for manufacturing the semiconductor device according to the third embodiment;

FIGS. 10A and 10B are diagrams (part 3) describing the example of the method for manufacturing the semiconductor device according to the third embodiment;

FIG. 11 is a diagram describing an example of a semiconductor package according to a fourth embodiment;

FIG. 12 is a diagram describing an example of a power factor correction circuit according to a fifth embodiment;

FIG. 13 is a diagram describing an example of a power supply device according to a sixth embodiment; and

FIG. 14 is a diagram describing an example of an amplifier according to a seventh embodiment.

### DESCRIPTION OF EMBODIMENTS

As for such an HEMT, a technology of providing a nitride semiconductor layer including an electron supply layer containing indium (In) above an electron transit layer, and a technology of providing a gate electrode, a source electrode, and a drain electrode above the nitride semiconductor layer are known. A technology is known in which an In desorption region having an In composition lower than an In composition of an electron transit layer side is provided in a surface layer portion of a region between a gate electrode and a source electrode and a region between the gate electrode and a drain electrode, in an In-containing layer having an In composition of, for example, 0.35 to 0.40 in a nitride semiconductor layer.

A technology is also known in which a recess reaching a carrier transit layer is provided in a barrier layer over the carrier transit layer, an InAlN (indium aluminum nitride) layer having an In composition ratio equal to or more than 17% and equal to or less than 18% is provided in the recess, and a source or drain electrode is provided over the InAlN layer.

A technology is also known in which a portion containing a III-N material is provided in a recess provided in a channel layer and an electron supply layer over the channel layer, a portion containing the III-N material and In of which a composition is increased toward an upper surface is further provided over the portion, and a source or drain contact is provided over the portion containing the III-N material and In.

Meanwhile, as a semiconductor device using a nitride semiconductor, a semiconductor device including an HEMT in which GaN is used for a channel layer and indium aluminum gallium nitride (InAlGaN) is used for a barrier layer is known. InAlGaN is a material that may realize a relatively high aluminum (Al) composition, and may obtain large spontaneous polarization by increasing the Al composition. By using InAlGaN for the barrier layer, it is expected that a two dimensional electron gas (2DEG) having a higher concentration may be generated in the channel layer and an output of the HEMT may be increased, as compared with a case where AlGaN is used.

Meanwhile, in a case where the nitride semiconductor containing In, Ga and Al having a relatively high composition is used for the barrier layer, the following may occur. For example, due to a large bandgap caused by the relatively high Al composition in the barrier layer, a barrier between a source electrode and a drain electrode that are provided over the barrier layer is increased, and a contact resistance between the channel layer and the source electrode and the drain electrode is increased. As the contact resistance is increased, an electric resistance of an electron transport path in the HEMT is increased, and a high-performance semiconductor device including the HEMT may not be realized.

An object according to one aspect of the present disclosure is to realize a semiconductor device that has a low contact resistance and high performance.

### First Embodiment

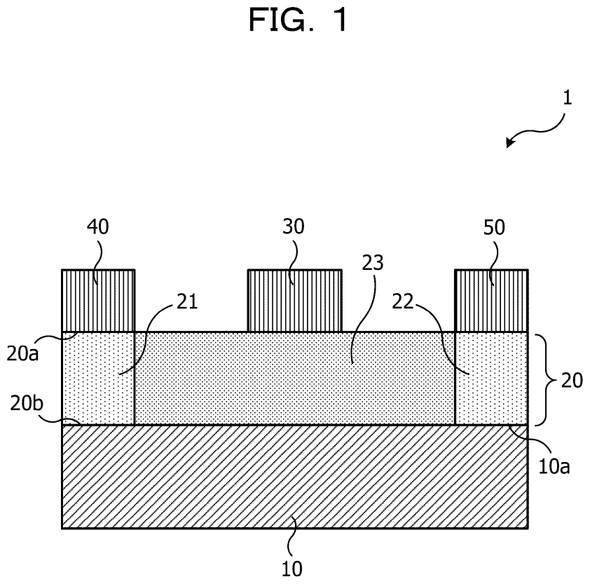

FIG. 1 is a diagram describing an example of a semiconductor device according to a first embodiment. FIG. 1 schematically illustrates a main portion cross-sectional diagram of the example of the semiconductor device.

A semiconductor device 1 illustrated in FIG. 1 is an example of a semiconductor device including an HEMT. The semiconductor device 1 includes a channel layer 10, a barrier layer 20, a gate electrode 30, a source electrode 40, and a drain electrode 50.

The channel layer 10 includes a nitride semiconductor (also referred to as a “first nitride semiconductor”) containing Ga. For example, GaN is used for the channel layer 10. Although not illustrated herein, the channel layer 10 is provided over a predetermined substrate. As the substrate, a silicon carbide (SiC) substrate, a GaN substrate, a silicon (Si) substrate, a sapphire substrate, or the like, or a substrate in which a nucleation layer is provided over such a substrate may be used.

The barrier layer 20 is provided on one surface 10a (also referred to as a “first surface”) side of the channel layer 10. The surface 10a of the channel layer 10 is, for example, a (0001) surface (c-surface, group III-polar surface). The barrier layer 20 includes a nitride semiconductor having a bandgap larger than a bandgap of the nitride semiconductor included in the channel layer 10. The barrier layer 20 includes the nitride semiconductor containing In, Al, and Ga (also referred to as a “second nitride semiconductor”).

The nitride semiconductor included in the barrier layer 20 includes regions in which compositions (also referred to as “composition ratios”) of In, Al, and Ga of group III elements contained in the nitride semiconductor are different from each other. The “composition” represents a ratio of the compositions of group III elements of the nitride semiconductor, for example, a composition of a specific group III element when the composition of the entire group III elements is set as 1.00. For example, the barrier layer 20 includes InAlGaN including regions having different compositions. As will be described below, AlGaN may be partially included in the barrier layer 20, in addition to InAlGaN having a certain composition. In this manner, the nitride semiconductor included in the barrier layer 20, for example, the nitride semiconductor containing In, Al, and Ga may include, for example, InAlGaN including the regions having different compositions, as well as InAlGaN having the certain composition and AlGaN.

The barrier layer 20 includes a first region 21 and a second region 22 having relatively low In compositions. The In composition of each of the first region 21 and the second region 22 is lower than an In composition of a third region 23 between the first region 21 and the second region 22. For example, the first region 21 and the second region 22 extend from one surface 20a (also referred to as a “second surface”) of the barrier layer 20 to the other surface 20b (also referred to as a “third surface”) opposite to the surface 20a. The third region 23 extends from one surface 20a of the barrier layer 20 to the other surface 20b opposite to the surface 20a. The first region 21 and the second region 22 having the lower In compositions than the In composition of the third region 23 are also referred to as the first region 21 and second region 22 of a “low In composition” in the following.

For example, the channel layer 10 and the barrier layer 20 are grown, by using a metal organic chemical vapor deposition (MOCVD) or metal organic vapor phase epitaxy (MOVPE) method or a molecular beam epitaxy (MBE) method. Heat treatment is performed on the barrier layer 20 containing In after the growth in a hydrogen atmosphere in a state in which regions in which the first region 21 and the second region 22 are to be formed are exposed and a region between the first region 21 and the second region 22 is covered with a protection film. By such heat treatment, In contained in the exposed regions of the barrier layer 20 is desorbed from the regions, and the first region 21 and the second region 22 having low In compositions are formed at the regions. The first region 21 and the second region 22 are formed, and the third region 23 is formed between the first region 21 and the second region 22.

In the semiconductor device 1, a 2DEG is generated, in the vicinity of a joining interface of the channel layer 10 with the barrier layer 20, by spontaneous polarization of the barrier layer 20 and piezoelectric polarization generated by distortion caused by a difference in lattice constants with the channel layer 10.

The gate electrode 30, the source electrode 40, and the drain electrode 50 are provided on the surface 20a side of the barrier layer 20 opposite to the channel layer 10 side. The surface 20a of the barrier layer 20 is, for example, a (0001) surface (c-surface, group III-polar surface). A predetermined metal is used for each of the gate electrode 30, the source electrode 40, and the drain electrode 50. The gate electrode 30 is provided between the source electrode 40 and the drain electrode 50. For example, the gate electrode 30 is provided so as to function as a Schottky electrode. The source electrode 40 and the drain electrode 50 are respectively provided on both sides of the gate electrode 30 so as to be spaced apart from the gate electrode 30. The source electrode 40 and the drain electrode 50 are provided so as to function as ohmic electrodes.

The first region 21 of the barrier layer 20 is a region facing the source electrode 40. The source electrode 40 is provided in the first region 21 having a low In composition of the barrier layer 20, for example, in the first region 21 in which the In composition is lower than a low In composition of the third region 23. It may also be said that the first region 21 having the low In composition in the barrier layer 20 is provided immediately below the source electrode 40. For example, the source electrode 40 is provided to be in contact with the first region 21.

The second region 22 of the barrier layer 20 is a region facing the drain electrode 50. The drain electrode 50 is provided in the second region 22 having a low In composition of the barrier layer 20, for example, in the second region 22 in which the In composition is lower than a low In composition of the third region 23. It may also be said that the second region 22 having the low In composition in the barrier layer 20 is provided immediately below the drain electrode 50. For example, the drain electrode 50 is provided to be in contact with the second region 22.

The third region 23 of the barrier layer 20 is a region between the first region 21 in which the source electrode 40 is provided and the second region 22 in which the drain electrode 50 is provided. For example, the third region 23 is a region extending from the first region 21 to the second region 22. The gate electrode 30 is provided in the third region 23 of the barrier layer 20, for example, in a part of the third region 23 in which an In composition is higher than the first region 21 and the second region 22, between the source electrode and the drain electrode 50, and apart from the source electrode 40 and the drain electrode 50. The third region 23 of the barrier layer 20 between the first region 21 and the second region 22 may also be referred to as a region including a portion at which the gate electrode 30 is provided, a portion between the gate electrode 30 and the source electrode 40, and a portion between the gate electrode 30 and the drain electrode 50.

At a time of an operation of the semiconductor device 1, a predetermined voltage is supplied between the source electrode 40 and the drain electrode 50, and a predetermined gate voltage is supplied to the gate electrode located between the source electrode 40 and the drain electrode 50. A transport path for an electron serving as a carrier is formed at the channel layer between the source electrode 40 and the drain electrode 50, and a transistor function of the semiconductor device 1 is realized.

A nitride semiconductor containing In, Al, and Ga is used for the barrier layer 20 in the semiconductor device 1. The first region 21 and the second region 22 having the low In compositions are provided, in the barrier layer 20. The first region 21 having the low In composition in the barrier layer 20 is provided immediately below the source electrode 40, and the second region 22 having the low In composition in the barrier layer 20 is provided immediately below the drain electrode 50. Therefore, even in a case where the nitride semiconductor containing In, Al, and Ga and having a relatively high Al composition is used for the barrier layer 20 in the semiconductor device 1, it is possible to suppress an increase in contact resistance between the source electrode 40 and the drain electrode 50, and the channel layer 10. This point will be described.

Generally, the nitride semiconductor containing In, Al, and Ga, for example, InAlGaN is known as a material capable of realizing a relatively high Al composition. By using InAlGaN having a relatively high Al composition for a barrier layer of an HEMT and obtaining large spontaneous polarization, it is expected that 2DEG having a higher concentration may be generated in a channel layer and an output of the HEMT may be increased, as compared with a case where AlGaN is used for the barrier layer. Meanwhile, in a case where InAlGaN having a relatively high Al composition is used for the barrier layer, a large bandgap by the Al composition causes a large barrier between a source electrode and a drain electrode that are provided over the barrier layer. As a result, a contact resistance between the channel layer and the source and drain electrodes is increased. As the contact resistance is increased, an electric resistance of an electron transport path in the HEMT is increased, and it becomes difficult to increase the output.

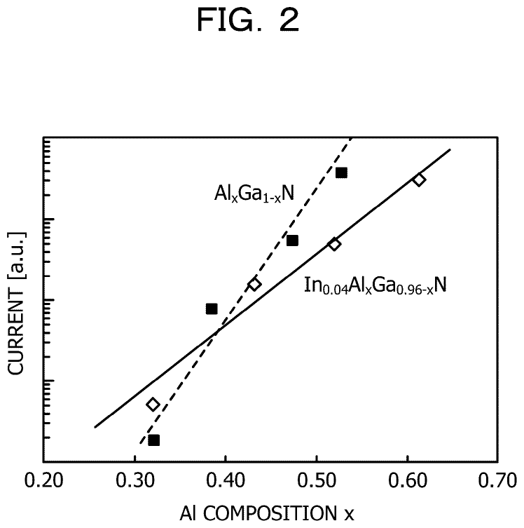

FIG. 2 is a diagram illustrating an example of a relationship between an Al composition and a current of a nitride semiconductor. FIG. 2 illustrates a dependence of a Schottky junction reverse direction current on an Al composition x in an AlₓGa₁₋ₓN layer and an In_{0.04}AlₓGa_{0.96-x}N layer. A horizontal axis represents the Al composition x, and a vertical axis represents the current.

With FIG. 2, both of the AlₓGa₁₋ₓN layer and the In_{0.04}AlₓGa_{0.96-x}N layer have a tendency that the current is increased as the Al composition x is increased. With FIG. 2, it is seen that when the Al composition x is equal to or more than 0.40 (equal to or more than 40%), a current of the AlₓGa₁₋ₓN layer not containing In is larger than a current of the In_{0.04}AlₓGa_{0.96-x}N layer containing In. For example, it is indicated that, when the Al composition x is in a range equal to or more than 0.40, an electric resistance is smaller in a layer having a smaller In composition. Accordingly, even in a case where the Al composition is relatively high as 0.40 or more, it may be said that the contact resistance may be reduced by using InAlGaN having a small In composition.

In the semiconductor device 1 described above, the first region 21 and the second region 22 having the low In compositions are provided immediately below the source electrode 40 and the drain electrode 50, respectively, in the barrier layer 20 in which the nitride semiconductor containing In, Al, and Ga is used.

For example, Al compositions of the first region 21 and the second region 22 in the barrier layer 20 of the semiconductor device 1 are set to be in a range equal to or more than 0.40. The In compositions of the first region 21 and the second region 22 in the barrier layer 20 are set to be in a range equal to or less than 0.05. For example, the first region 21 and the second region 22 having the low In compositions are formed by performing heat treatment in a hydrogen atmosphere as described above, on the barrier layer 20 of InAlGaN grown to a predetermined initial composition over the channel layer 10 and desorbing a part of In of the barrier layer 20. The first region 21 and the second region 22 having the low In compositions may be nitride semiconductors containing In (for example, InAlGaN having an In composition of more than 0.00) or nitride semiconductors not containing In (for example, AlGaN having an In composition of 0.00). At a time when the first region 21 and the second region 22 are formed by desorbing In by the heat treatment, the barrier layer 20 is grown over the channel layer 10 with the initial composition such that the first region 21 and the second region 22 to be formed have the Al compositions and the In compositions within the ranges described above.

As the initial composition of the barrier layer 20, for example, the Al composition is set to be in a range equal to or more than 0.10 and less than 1.00. As the initial composition of the barrier layer 20, for example, the In composition is set to be in a range, which is more than 0.00 and equal to or less than 0.20. In regions of the barrier layer 20 in which the first region 21 and the second region 22 are to be formed, which are set to have such an initial composition, In is desorbed by the heat treatment described above, so that the first region 21 and the second region 22 having the In compositions in a range equal to or less than 0.05 are formed. By the desorption of In, the In amount is decreased and the Al amount relatively is increased, so that the first region 21 and the second region 22 having the Al compositions in a range equal to or more than 0.40 are formed. At a time when the first region 21 and the second region 22 are formed, the third region 23, which is located between the first region 21 and the second region 22 and from which the desorption of In is suppressed, may have the same or substantially the same composition as the initial composition of the barrier layer 20. The barrier layer 20 including the first region 21, the second region 22, and the third region 23 having the compositions as described above exhibits tensile distortion, and a 2DEG is generated in the channel layer 10 to which the barrier layer 20 is joined.

In the semiconductor device 1, the first region 21 and the second region 22 having the low In compositions as described above are provided immediately below the source electrode 40 and the drain electrode 50, respectively, in the barrier layer 20 in which the nitride semiconductor containing In, Al, and Ga is used. Therefore, in the semiconductor device 1, an increase in contact resistance between the source electrode 40 and the drain electrode 50, and the channel layer 10 is suppressed. By suppressing the increase in contact resistance, an increase in resistance of an electron transport path extending from the source electrode 40 to the drain electrode 50 is suppressed, and a high output of the semiconductor device 1 is realized.

In the related art, as technologies for reducing a contact resistance between a source electrode and a drain electrode, and a channel layer, for example, a regrowth layer formation technology or a pit-assisted etching technology is known. The regrowth layer formation technology is a technology in which a recess that penetrates through a barrier layer and reaches a channel layer is provided, a regrowth layer (an n-type GaN layer or the like) doped with a predetermined dopant is provided in the recess, and a source electrode and a drain electrode are provided over the regrowth layer. The pit-assisted etching technology is a technology in which pits are formed at a barrier layer by etching using crystal dislocations of the barrier layer as starting points, and a part of a source electrode and a part of a drain electrode are formed at the formed pits. Meanwhile, among these technologies, in the regrowth layer formation technology, the number of steps is increased along with the formation of the recess and the formation of the regrowth layer in manufacture of the semiconductor device. In the pit-assisted etching technology, the barrier layer grown over a substrate having a low crystal dislocation density such as a GaN free-standing substrate via a channel layer also has a low crystal dislocation density. Therefore, the number of pits formed at the barrier layer is decreased, and an electrode portion formed at the pits is also decreased, so that a sufficient contact resistance reduction effect may not be obtained.

By contrast, the first region 21 and the second region 22 having the low In compositions in the barrier layer 20 of the semiconductor device 1 described above are formed by performing heat treatment in a hydrogen atmosphere on the barrier layer 20 after growth in a state in which the regions in which the first region 21 and the second region 22 are to be formed are exposed. By the heat treatment in the hydrogen atmosphere, In is desorbed from the exposed regions of the barrier layer 20 after the growth, and the first region 21 and the second region 22 having the low In compositions are formed. By the first region 21 and the second region 22 formed in this manner in the semiconductor device 1, the contact resistance between the source electrode 40 and the drain electrode 50, and the channel layer 10 is reduced. Accordingly, it is possible to realize the high-performance semiconductor device 1 having a low contact resistance while suppressing an increase in the number of steps as in the case where the regrowth layer formation technology as described above is employed. It is possible to realize the high-performance semiconductor device 1 having a low contact resistance by suppressing a dependence on the crystal dislocation density of the barrier layer 20 and the channel layer 10 below the barrier layer 20, or the substrate, as in the case where the pit-assisted etching technology as described above is employed.

### Second Embodiment

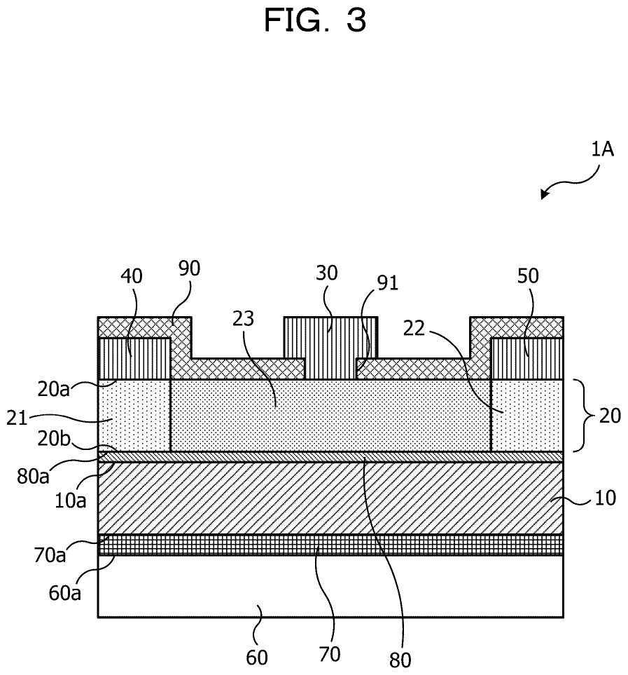

FIG. 3 is a diagram describing an example of a semiconductor device according to a second embodiment. FIG. 3 schematically illustrates a main portion cross-sectional diagram of the example of the semiconductor device.

A semiconductor device 1A illustrated in FIG. 3 is an example of a semiconductor device including an HEMT. The semiconductor device 1A includes a base substrate 60, a nucleation layer 70, the channel layer 10, a spacer layer 80, the barrier layer 20, the gate electrode 30, the source electrode 40, the drain electrode 50, and a passivation film 90.

As the channel layer 10, the barrier layer 20, the gate electrode 30, the source electrode 40, and the drain electrode 50 in the semiconductor device 1A, devices in the same manner as the semiconductor device 1 (FIG. 1) described in the first embodiment described above are used.

For example, a semi-insulating SiC substrate is used as the base substrate 60 of the semiconductor device 1A. Alternatively, a conductive SiC substrate, a GaN substrate, a Si substrate, a sapphire substrate, or the like may be used for the base substrate 60. The nucleation layer 70 is provided on one surface 60a of the base substrate 60. For example, aluminum nitride (AlN) is used for the nucleation layer 70.

The channel layer 10 as described in the first embodiment described above, for example, the channel layer 10 of GaN is provided on a surface 70a side of the nucleation layer 70 opposite to the base substrate 60 side. The surface 70a of the nucleation layer 70 is, for example, a (0001) surface (c-surface, group III-polar surface).

The spacer layer 80 is provided on the surface 10a ((0001) surface) side of the channel layer 10 opposite to the nucleation layer 70 side. The spacer layer 80 includes a nitride semiconductor having a bandgap larger than a bandgap of a nitride semiconductor included in the channel layer 10. The spacer layer 80 includes the nitride semiconductor containing Al (also referred to as a “third nitride semiconductor”). For example, AlGaN, AlN, or the like having a bandgap larger than a bandgap of GaN of the channel layer 10 is used for the spacer layer 80.

The barrier layer 20 as described in the first embodiment described above is provided on a surface 80a side of the spacer layer 80 opposite to the channel layer 10 side. The surface 80a of the spacer layer 80 is, for example, a (0001) surface (c-surface, group III-polar surface). A nitride semiconductor containing In, Al, and Ga is used for the barrier layer 20. The nitride semiconductor of the barrier layer 20 has regions in which compositions (composition ratios) of In, Al, and Ga of group III elements contained in the nitride semiconductor are different from each other. The nitride semiconductor included in the barrier layer 20, for example, the nitride semiconductor containing In, Al, and Ga may include, for example, InAlGaN including the regions having different compositions, as well as InAlGaN having the certain composition and AlGaN.

The barrier layer 20 includes the first region 21 and the second region 22 having low In compositions. The In composition of each of the first region 21 and the second region 22 is lower than an In composition of the third region 23 between the first region 21 and the second region 22. The In composition of the third region 23 is in a range, which is more than 0.00 and equal to or less than 0.20. An Al composition of the third region 23 is in a range equal to or more than 0.10 and less than 1.00. The In compositions of the first region 21 and the second region 22 are set to be in a range equal to or less than 0.05. Al compositions of the first region 21 and the second region 22 are set to be in a range equal to or more than 0.40. In a case where the In compositions of the first region 21 and the second region 22 exceed 0.00, the first region 21, the second region 22, and the third region 23 are InAlGaN. In a case where the In compositions of the first region 21 and the second region 22 are 0.00, the first region 21 and the second region 22 are AlGaN, and the third region 23 is InAlGaN. For example, the first region 21 and the second region 22 are provided so as to extend from one surface 20a to the other surface 20b of the barrier layer 20.

The gate electrode 30, the source electrode 40, and the drain electrode 50 as described in the first embodiment described above are provided on the surface 20a ((0001) surface) side of the barrier layer 20 opposite to the channel layer 10 (or the spacer layer 80) side. The gate electrode 30 is provided in a part of the third region 23 of the barrier layer 20. For example, the gate electrode 30 is provided so as to function as a Schottky electrode. The source electrode 40 is provided in the first region 21 of the barrier layer 20, and the drain electrode 50 is provided in the second region 22 of the barrier layer 20. The source electrode 40 and the drain electrode 50 are provided so as to function as ohmic electrodes. The third region 23 of the barrier layer 20 between the first region 21 and the second region 22 is a region including a portion at which the gate electrode 30 is provided, a portion between the gate electrode 30 and the source electrode 40, and a portion between the gate electrode 30 and the drain electrode 50.

The passivation film 90 is provided so as to cover the barrier layer the source electrode 40, and the drain electrode 50. An opening portion 91 leading to the barrier layer 20 is formed at the passivation film 90. The gate electrode 30 is provided at a position of the opening portion 91 of the passivation film 90. For example, any of various insulating materials such as oxides, nitrides, and oxynitrides is used for the passivation film 90. For example, silicon nitride (SiN) is used for the passivation film 90.

Preferably, in the semiconductor device 1A, a nitride semiconductor containing In, Al, and Ga and having a relatively high Al composition is used for the barrier layer 20 over the channel layer 10. Therefore, relatively large spontaneous polarization (for example, as compared with AlGaN) is obtained, and high concentration of a 2DEG generated in the channel layer 10 and a high output of the semiconductor device 1A by the high concentration are realized.

In the semiconductor device 1A, the first region 21 and the second region 22 having low In compositions, for example, the first region 21 and the second region 22 having an Al composition equal to or more than 0.40 and an In composition equal to or less than 0.05 are provided in the barrier layer 20 in which a nitride semiconductor containing In, Al, and Ga is used. The first region 21 having the low In composition is provided immediately below the source electrode 40, and the second region 22 having the low In composition is provided immediately below the drain electrode 50. As compared with the third region 23 between the first region 21 and the second region 22, an electric resistance of the first region 21 and the second region 22 having the low In compositions is low.

Accordingly, in the semiconductor device 1A, a contact resistance between the source electrode 40 and the drain electrode 50, and the channel layer 10 is reduced, as compared with a case where the In compositions of the first region 21 and the second region 22 are not smaller than the In composition of the third region 23, for example, a case where the In compositions of the first region 21 and the second region 22 are the same as the In composition of the third region 23. At this time, by setting the In composition of the third region 23 to be equal to or less than 0.20, tensile distortion appears in the third region 23 between the source electrode 40 and the drain electrode 50, and a high-concentration 2DEG is generated in the channel layer 10.

In the semiconductor device 1A, reducing the contact resistance of the source electrode 40 and the drain electrode 50, and the channel layer 10 suppresses an increase in resistance of an electron transport path formed between the source electrode 40 and the drain electrode 50 via the channel layer 10 and an increase in on-resistance. With the configuration described above, the high-performance semiconductor device 1A having a low contact resistance, a low on-resistance, and a high output is realized.

Next, a method for manufacturing the semiconductor device 1A having the configuration described above will be described with reference to FIGS. 4A to 6B and FIG. 3 described above.

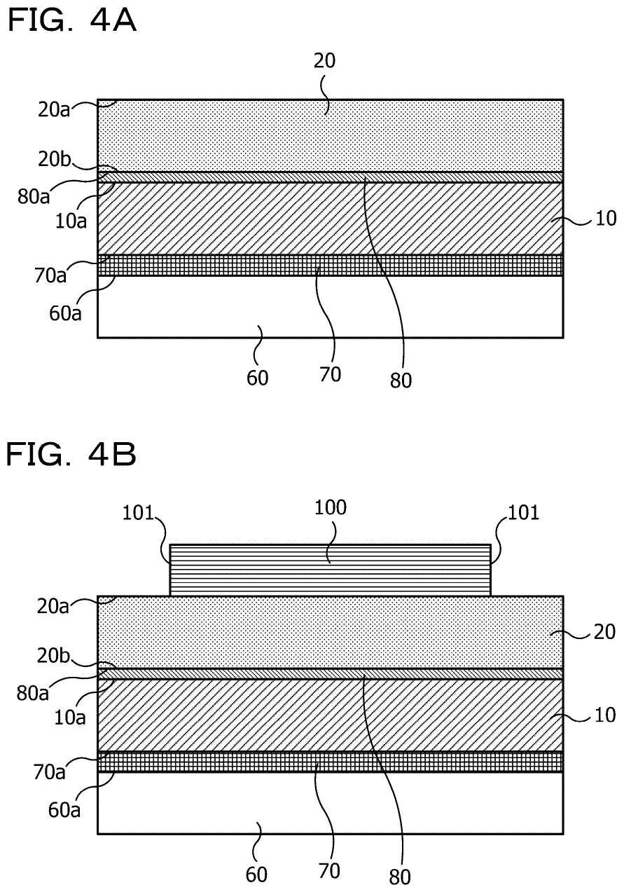

FIGS. 4A to 6B are diagrams describing an example of a method for manufacturing the semiconductor device according to the second embodiment. Each of FIGS. 4A, 4B, 5A, 5B, 6A, and 6B schematically illustrates a main portion cross-sectional diagram of each step in manufacturing the semiconductor device.

First, as illustrated in FIG. 4A, a stack structure in which the nucleation layer 70, the channel layer 10, the spacer layer 80, and the barrier layer 20 are sequentially grown is formed over the base substrate 60.

For example, the nucleation layer 70 of AlN is grown over the surface 60a of the base substrate 60 of semi-insulating SiC, by using an MOVPE method. A thickness of the nucleation layer 70 is set to, for example, 100 nm. The channel layer 10 of GaN is grown over the surface 70a of the nucleation layer 70, by using the MOVPE method. A thickness of the channel layer 10 is set to, for example, 3 μm. The spacer layer 80 of AlGaN or AlN (composition formula AlₛGa₁₋ₛN) is grown over the surface 10a of the channel layer 10, by using the MOVPE method. A thickness of the spacer layer 80 is set to, for example, 2 nm. An Al composition s of the spacer layer 80 of AlₛGa₁₋ₛN is set to, for example, 0.40≤s≤1.00. The barrier layer 20 of InAlGaN (composition formula In_{y}Al_{z}Ga_{1-y-z}N) of an initial composition is grown over the surface 80a of the spacer layer by using the MOVPE method. A thickness of the barrier layer 20 is set to, for example, 6 nm. An Al composition z of the barrier layer 20 of In_{y}Al_{z}Ga_{1-y-z}N having an initial composition is set to, for example, 0.10≤z<1.00. An In composition y of the barrier layer 20 of In_{y}Al_{z}Ga_{1-y-z}N having an initial composition is set to, for example, 0.00<y≤0.20. Meanwhile, 0.00<y+z<1.00 is set.

A mixed gas of tri-methyl-gallium (TMGa), which is a Ga source, and ammonia (NH₃) is used for growth of GaN, in the growth of each of the nitride semiconductor layers (the nucleation layer 70, the channel layer 10, the spacer layer 80, and the barrier layer 20) by using the MOVPE method. A mixed gas of TMGa, NH₃, and tri-methyl-aluminum (TMAl), which is an Al source, is used for growth of AlGaN. A mixed gas of TMAl and NH₃ is used for growth of AlN. A mixed gas of TMAl, TMGa, NH₃, and tri-methyl-indium (TMIn), which is an In source, is used for growth of InAlGaN. Supply and stop (switching) of TMGa, TMAl, and TMIn and flow rates thereof (mixing ratios with other raw materials) during the supply are set as appropriate, depending on the nitride semiconductor to be grown. As a carrier gas, hydrogen (H₂) or nitrogen (N₂) is used. A pressure condition during the growth is set to be in a range from approximately 1 kPa to approximately 100 kPa. A temperature condition during the growth is set to be in a range from approximately 700° C. to approximately 1200° C.

Although an example in which the spacer layer 80 is provided is described here, the barrier layer 20 may be grown directly over the channel layer 10, without providing the spacer layer 80.

After the stack structure in which the nucleation layer 70, the channel layer 10, the spacer layer 80, and the barrier layer 20 are sequentially grown is formed over the base substrate 60, an inter-element isolation region (not illustrated) is formed. For example, first, a mask (not illustrated) having an opening portion in a region in which an inter-element isolation region is to be formed is formed by using a photolithography technology. Dry etching using a chlorine-based gas or implantation of ion such as argon (Ar) is performed on the nitride semiconductor layer in the opening portion of the mask to form the inter-element isolation region. After the formation of the inter-element isolation region, the mask is removed.

After the formation of the stack structure of the nitride semiconductor layers and the inter-element isolation region as described above, a surface protection film 100 (also referred to as a “protection film”) having opening portions 101 in regions in which the first region 21 and the second region 22 are to be formed as described below is formed over the surface 20a of the barrier layer 20, as illustrated in FIG. 4B. For example, any of various insulating materials such as oxides, nitrides, and oxynitrides each containing at least one of Si, Al, hafnium (Hf), zirconium (Zr), titanium (Ti), tantalum (Ta), and tungsten (W) is used for the surface protection film 100. For example, SiN is used for the surface protection film 100. A plasma chemical vapor deposition (CVD) method is used to form the surface protection film 100. Alternatively, an atomic layer deposition (ALD) method, a sputtering method, or the like may be used to form the surface protection film 100. The surface protection film 100 having the opening portions 101 is obtained as follows. For example, a material of the surface protection film 100 is formed over the entire surface by using the plasma CVD method or the like, and then the opening portions 101 are formed at predetermined regions by using the photolithography technology and the dry etching using a chlorine-based or fluorine-based gas.

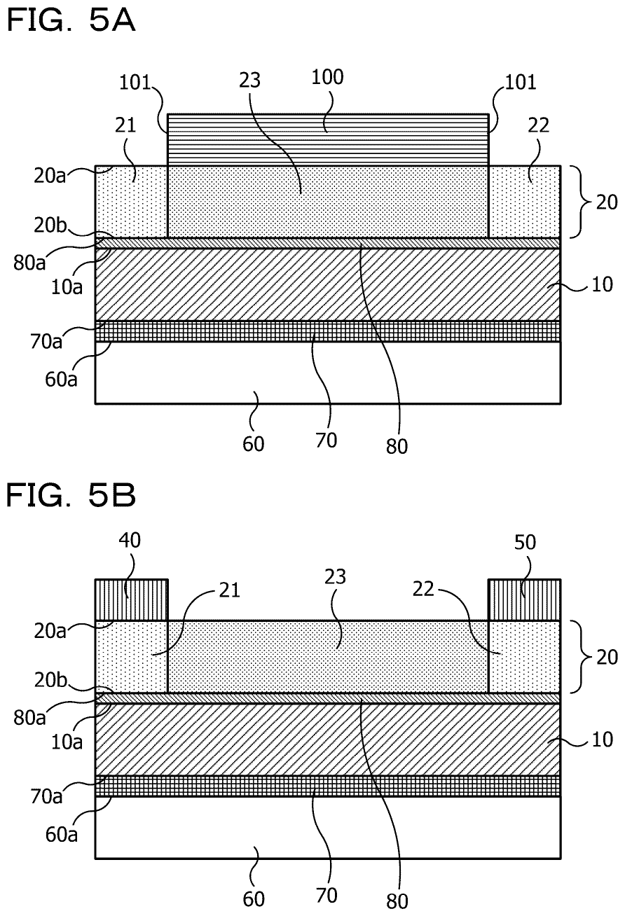

After the formation of the surface protection film 100 having the opening portions 101, as illustrated in FIG. 5A, the first region 21 and the second region 22 having low In compositions are formed at the barrier layer 20 exposed through the opening portion 101 of the surface protection film 100. At the time of the formation of the first region 21 and the second region 22, in a state in which the barrier layer 20 is exposed through the opening portion 101 of the surface protection film 100, heat treatment is performed in a hydrogen atmosphere, under a temperature condition in a range of 600° C. to 800° C., for example, at a temperature of 700° C. By performing such heat treatment, In is desorbed from a region of the barrier layer 20 exposed through the opening portion 101 of the surface protection film 100. Therefore, the first region 21 and the second region 22 having the low In compositions are formed at the region of the barrier layer 20 exposed through the opening portion 101 of the surface protection film 100. For example, by the heat treatment, the first region 21 and the second region 22 having the Al composition z of 0.40≤z<1.00 and the In composition y of 0≤x≤0.05 (meanwhile, 0.00<y+z<1.00) of In_{y}Al_{z}Ga_{1-y-z}N are formed. A region between the first region 21 and the second region 22, for example, a region in which the desorption of In is suppressed by being covered with the surface protection film 100 becomes the third region 23 having a higher In composition than the In compositions the first region 21 and the second region 22. For example, the third region 23 of In_{y}Al_{z}Ga_{1-y-z}N having an initial composition as described above is formed.

For example, the first region 21 and the second region 22 having the low In compositions are formed so as to extend from one surface 20a to the other surface 20b of the barrier layer 20, for example, so as to be in contact with the surface 80a of the spacer layer 80 (the surface 10a of the channel layer 10 in a case where the spacer layer 80 is not provided). With the formation in this manner, the barrier layer 20 between the channel layer 10, and the source electrode 40 and the drain electrode 50 formed on the first region 21 and the second region 22, respectively, as described below is occupied by the first region 21 and the second region 22 having low electric resistances by the low In composition. Therefore, it is possible to reduce a contact resistance between the channel layer 10, and the source electrode 40 and the drain electrode 50, as compared with a case where the barrier layer 20 between the channel layer 10, and the source electrode 40 and the drain electrode 50 is partially made with a low In composition, for example, only a surface layer portion has the low In composition.

After the formation of the first region 21 and the second region 22 of the barrier layer 20, the surface protection film 100 is removed. After the removal of the surface protection film 100, as illustrated in FIG. 5B, the source electrode 40 and the drain electrode 50 are formed on the first region 21 and the second region 22 formed at the barrier layer 20, respectively. At this time, first, an electrode metal is formed at each of the first region 21 at which the source electrode 40 is to be formed and the second region 22 at which the drain electrode 50 is to be formed, by using the photolithography technology, a vapor deposition technology, and a lift-off technology. For example, a stack of Ta having a thickness of 20 nm and Al having a thickness of 200 nm is formed as the electrode metal. After the formation of the electrode metal, heat treatment is performed under a temperature condition in a range of 400° C. to 1000° C., for example, at a temperature of 550° C. in a nitrogen atmosphere to build an ohmic contact of the electrode metal. Therefore, the source electrode 40 and the drain electrode 50 are formed on the first region 21 and the second region 22, respectively.

A region of the barrier layer 20 facing the source electrode 40, for example, a region immediately below the source electrode 40 is the first region 21 having the low In composition. A region of the barrier layer 20 facing the drain electrode 50, for example, a region immediately below the drain electrode is the second region 22 having the low In composition.

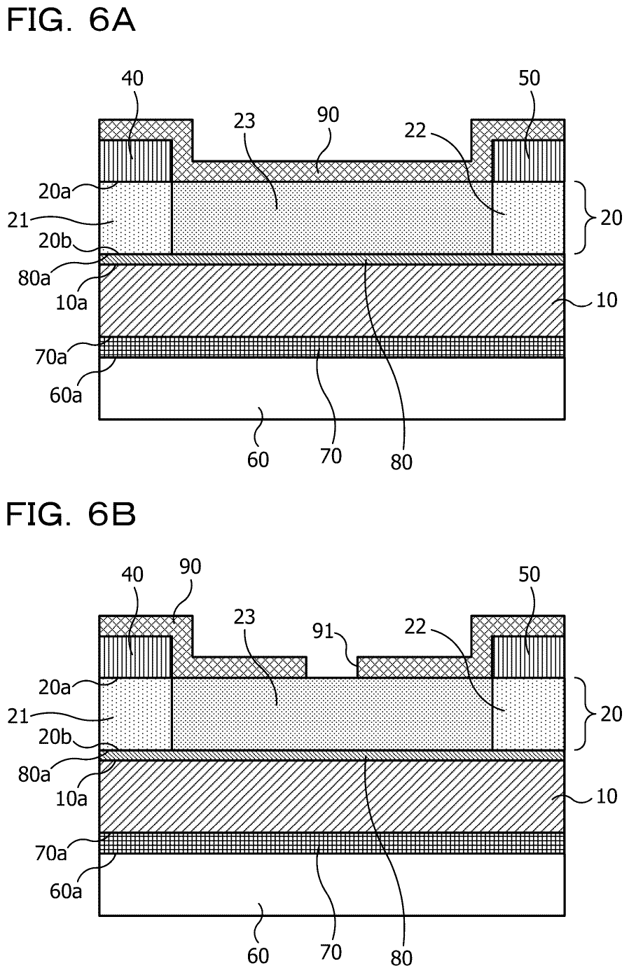

After the formation of the source electrode 40 and the drain electrode 50, as illustrated in FIG. 6A, the passivation film 90 is formed so as to cover the barrier layer 20, the source electrode 40, and the drain electrode 50. For example, the passivation film 90 of SiN or the like having a film thickness in a range from 2 nm to 500 nm, for example, having a film thickness of 100 nm is formed by using the plasma CVD method. An ALD method, a sputtering method, or the like may be used to form the passivation film 90.

After the formation of the passivation film 90, as illustrated in FIG. 6B, the passivation film 90 in a region in which the gate electrode 30 is to be formed is partially removed to form the opening portion 91 leading to the barrier layer 20. In this case, first, a mask (not illustrated) having an opening portion in the region where the gate electrode 30 is to be formed is formed by using the photolithography technology, and dry etching is performed. The passivation film exposed through the opening portion of the mask is removed by this etching, and the opening portion 91 of the passivation film 90 is formed. The etching of the passivation film 90 is performed by, for example, dry etching using a fluorine-based or chlorine-based gas. Alternatively, the passivation film 90 may be etched by wet etching using hydrofluoric acid, buffered hydrofluoric acid, or the like. After the formation of the opening portion 91 by etching the passivation film 90, the mask is removed.

After the formation of the opening portion 91 of the passivation film 90, as illustrated in FIG. 3 described above, the gate electrode 30 is formed at a position of the opening portion 91. In this case, an electrode metal is formed at the position of the opening portion 91 of the passivation film 90 by using the photolithography technology, the vapor deposition technology, and the lift-off technology. For example, a stack of nickel (Ni) having a thickness of 30 nm and gold (Au) having a thickness of 400 nm is formed as the electrode metal. The electrode metal is formed over the upper surface of the passivation film 90, and is also formed to enter the opening portion 91. The gate electrode 30 that functions as a Schottky electrode is thereby formed.

By the steps in this manner, the semiconductor device 1A as illustrated in FIG. 3 described above is manufactured.

As described above, in the semiconductor device 1A, the first region 21 having the low In composition in the barrier layer 20 is provided immediately below the source electrode 40, and the second region 22 having the low In composition in the barrier layer 20 is provided immediately below the drain electrode 50. Therefore, in the semiconductor device 1A, a contact resistance between the source electrode 40 and the drain electrode 50, and the channel layer 10 is reduced. By reducing the contact resistance, an increase in resistance of an electron transport path formed between the source electrode 40 and the drain electrode 50 via the channel layer 10 and an increase in on-resistance of the electron transport path are suppressed. Accordingly, the high-performance semiconductor device 1A having a low contact resistance, a low on-resistance, and a high output is realized.

In the manufacturing of the semiconductor device 1A, the first region 21 and the second region 22 having the low In compositions of the barrier layer 20 are formed by desorbing In by heat treatment in a hydrogen atmosphere. Therefore, it is possible to realize the high-performance semiconductor device 1A having a low contact resistance while suppressing an increase in the number of steps as in the case where a regrowth layer formation technology is employed. It is possible to realize the high-performance semiconductor device 1A having a low contact resistance by suppressing a dependence on a crystal dislocation density of the barrier layer 20 and the channel layer 10 below the barrier layer 20, or the base substrate 60, as in the case where the pit-assisted etching technology is employed.

In the semiconductor device 1A, the types of metals and the layer structures of the gate electrode 30, the source electrode 40, and the drain electrode 50 are not limited to the examples described above, and the methods for forming the gate electrode 30, the source electrode 40, and the drain electrode 50 are not limited to the examples described above. Each of the gate electrode 30, the source electrode 40, and the drain electrode 50 may have a single-layer structure or a stack structure. At the time of the formation of the source electrode 40 and the drain electrode 50, the heat treatment as described above does not have to be performed as long as the ohmic contact is realized by the formation of the electrode metals for these electrodes. At the time of the formation of the gate electrode 30, heat treatment may be further performed after the formation of the electrode metal for the gate electrode 30.

Although an example in which the gate electrode 30 functioning as a Schottky electrode is provided in the semiconductor device 1A is described here, a gate insulating film using oxides, nitrides, oxynitrides, or the like may be provided between the gate electrode 30 and the barrier layer 20 to form a metal insulator semiconductor (MIS) type gate structure.

### Third Embodiment

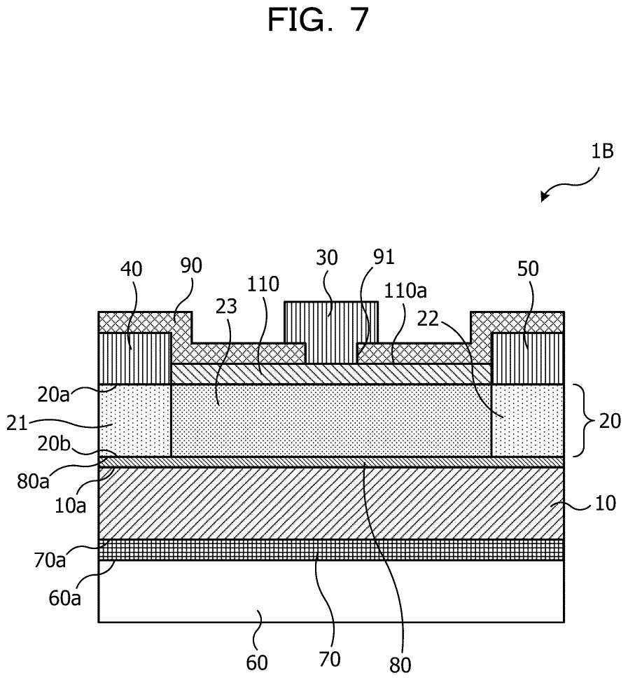

FIG. 7 is a diagram describing an example of a semiconductor device according to a third embodiment. FIG. 7 schematically illustrates a main portion cross-sectional diagram of the example of the semiconductor device.

A semiconductor device 1B illustrated in FIG. 7 is an example of a semiconductor device including an HEMT. The semiconductor device 1B has a configuration in which a cap layer 110 is provided on the surface 20a side of the barrier layer 20 opposite to the channel layer 10 (or the spacer layer 80) side. The semiconductor device 1B is different from the semiconductor device 1A described in the second embodiment described above in that the semiconductor device 1B has such a configuration.

As the channel layer 10, the barrier layer 20, the gate electrode 30, the source electrode 40, and the drain electrode 50 in the semiconductor device 1B, devices in the same manner as the semiconductor device 1 (FIG. 1) described in the first embodiment described above and the semiconductor device 1A (FIG. 3 or the like) described in the second embodiment described above are used. In the semiconductor device 1B, the base substrate 60, the nucleation layer 70, the spacer layer 80, and the passivation film 90 in the same manner as those of the semiconductor device 1A (FIG. 3 and the like) described in the second embodiment described above are used.

The cap layer 110 is provided on the surface 20a ((0001) surface) side of the barrier layer 20. The passivation film 90 and the gate electrode 30 located at the opening portion 91 of the passivation film 90 are provided on a surface 110a side of the cap layer 110 opposite to the barrier layer 20 side. The surface 110a of the cap layer 110 is, for example, a (0001) surface (c-surface, group III-polar surface). The gate electrode 30 is provided on the surface 20a side of the barrier layer 20 via the cap layer 110. The cap layer 110 includes a nitride semiconductor containing Ga (also referred to as a “fourth nitride semiconductor”). For example, AlGaN, GaN, or the like is used for the cap layer 110.

In the semiconductor device 1B, the barrier layer 20 is protected, with such a cap layer 110. For example, in a case where a nitride semiconductor of InAlGaN or the like containing In is used for the barrier layer 20, the following may occur. For example, when the barrier layer 20 is exposed to etching when the opening portion 91 of the passivation film 90 is formed or heat in a step involving heating, a relatively weak bond between In and N (nitrogen) is broken to cause a defect, or In is desorbed from the barrier layer 20. Damage such as generation of such a defect or the desorption of In is likely to be inflicted on the barrier layer 20 containing In. When such damage is inflicted on the barrier layer an increase in leakage current or the like may be caused.

By contrast, when the cap layer 110 is provided over the surface of the barrier layer 20 as in the semiconductor device 1B, damage inflicted on the barrier layer 20 such as the desorption of In due to heat or the generation of a defect due to etching may be suppressed. Therefore, the high-performance semiconductor device 1B in which an increase in leakage current or the like is suppressed is realized.

Next, a method for manufacturing the semiconductor device 1B having the configuration described above will be described with reference to FIGS. 8A to 10B and FIG. 7 described above.

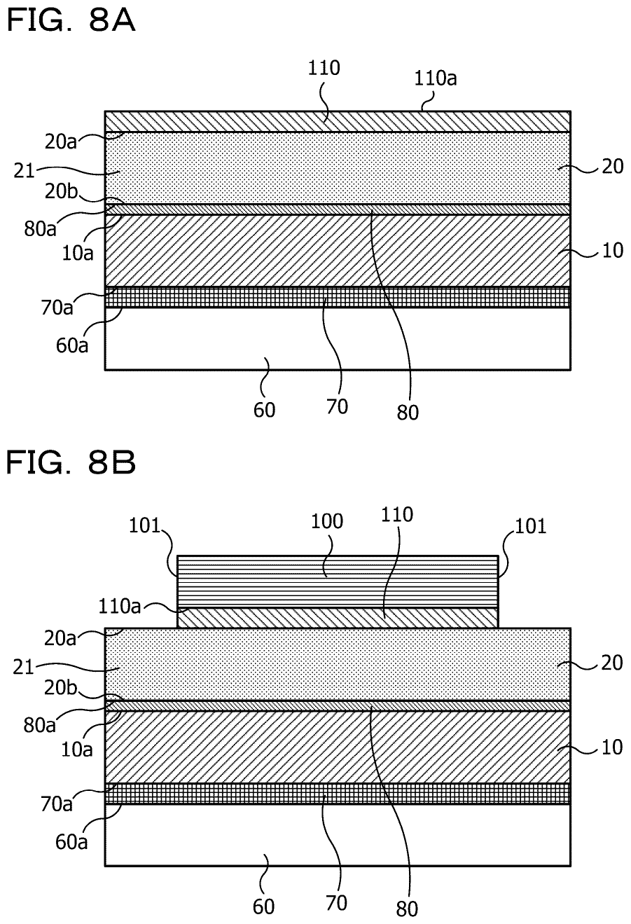

FIG. 8A to FIG. 10B are diagrams describing an example of a method for manufacturing the semiconductor device according to the third embodiment. Each of FIGS. 8A, 8B, 9A, 9B, 10A, and 10B schematically illustrates a main portion cross-sectional diagram of each step in manufacturing the semiconductor device.

First, as illustrated in FIG. 8A, a stack structure in which the nucleation layer 70, the channel layer 10, the spacer layer 80, the barrier layer and the cap layer 110 are sequentially grown is formed over the base substrate 60.

For example, the nucleation layer 70 of AlN is grown over the surface 60a of the base substrate 60 of semi-insulating SiC, by using the MOVPE method. The thickness of the nucleation layer 70 is set to, for example, 100 nm. The channel layer 10 of GaN is grown over the surface 70a of the nucleation layer 70, by using the MOVPE method. The thickness of the channel layer 10 is set to, for example, 3 μm. The spacer layer 80 of AlGaN or AlN (composition formula AlₓGa₁₋ₓN) is grown over the surface 10a of the channel layer 10, by using the MOVPE method. The thickness of the spacer layer 80 is set to, for example, 2 nm. An Al composition x of the spacer layer 80 of AlₓGa₁₋ₓN is set to, for example, 0.40×1.00. The barrier layer 20 of InAlGaN (composition formula In_{y}Al_{z}Ga_{1-y-z}N) of an initial composition is grown over the surface 80a of the spacer layer 80, by using the MOVPE method. The thickness of the barrier layer 20 is set to, for example, 6 nm. The Al composition z of the barrier layer 20 of In_{y}Al_{z}Ga_{1-y-z}N having an initial composition is set to, for example, 0.10≤z<1.00. The In composition y of the barrier layer 20 of In_{y}Al_{z}Ga_{1-y-z}N having an initial composition is set to, for example, 0.00<y≤0.20. Meanwhile, 0.00<y+z<1.00 is set.

The cap layer 110 of AlGaN or GaN (composition formula AlₜGa₁₋ₜN) is grown over the surface 20a of the barrier layer 20 by using the MOVPE method. A thickness of the cap layer 110 is set to, for example, 4 nm. An Al composition t of the cap layer 110 of AlₜGa₁₋ₜN is set to, for example, 0.00≤t<1.00. When Al is contained in the cap layer 110, diffusion of In contained in the barrier layer 20 into the cap layer 110 is suppressed, as compared with a case where Al is not contained.

A mixed gas of TMGa, which is a Ga source, and NH₃ is used for growth of GaN, in the growth of each of the nitride semiconductor layers (the nucleation layer 70, the channel layer 10, the spacer layer 80, and the barrier layer 20) by using the MOVPE method. A mixed gas of TMAl, which is an Al source, TMGa, and NH₃ is used for growth of AlGaN. A mixed gas of TMAl and NH₃ is used for growth of AlN. A mixed gas of TMIn, which is an In source, TMAl, TMGa, and NH₃ is used for growth of InAlGaN. Supply and stop (switching) of TMGa, TMAl, and TMIn and flow rates thereof (mixing ratios with other raw materials) during the supply are set as appropriate, depending on the nitride semiconductor to be grown. As the carrier gas, H₂ or N₂ is used. The pressure condition during the growth is set to be in a range from approximately 1 kPa to approximately 100 kPa. The temperature condition during the growth is set to be in a range from approximately 700° C. to approximately 1200° C.

Although an example in which the spacer layer 80 is provided is described here, the barrier layer 20 may be grown directly over the channel layer 10, without providing the spacer layer 80.

After the stack structure in which the nucleation layer 70, the channel layer 10, the spacer layer 80, the barrier layer 20, and the cap layer 110 are sequentially grown is formed over the base substrate 60, an inter-element isolation region (not illustrated) is formed. For example, first, a mask (not illustrated) having an opening portion in a region in which an inter-element isolation region is to be formed is formed by using the photolithography technology. Dry etching using a chlorine-based gas or implantation of ion such as Ar is performed on the nitride semiconductor layer in the opening portion of the mask to form the inter-element isolation region. After the formation of the inter-element isolation region, the mask is removed.

After the formation of the stack structure of the nitride semiconductor layers and the inter-element isolation region as described above, the surface protection film 100 having opening portions 101 in regions in which the first region 21 and the second region 22 are to be formed as described below is formed over the surface 110a of the cap layer 110, as illustrated in FIG. 8B. For example, various insulating materials such as oxides, nitrides, and oxynitrides containing at least one of Si, Al, Hf, Zr, Ti, Ta, and W are used for the surface protection film 100. For example, SiN is used for the surface protection film 100. The plasma CVD method is used to form the surface protection film 100. Alternatively, the ALD method, the sputtering method, or the like may be used to form the surface protection film 100. The surface protection film 100 having the opening portions 101 is obtained as follows. For example, a material of the surface protection film 100 is formed over the entire surface by using the plasma CVD method or the like, and then the opening portions 101 are formed at predetermined regions by using the photolithography technology and the dry etching using a chlorine-based or fluorine-based gas.

At the time of the formation of the opening portion 101 of the surface protection film 100, as illustrated in FIG. 8B, a portion of the cap layer 110 exposed by the formation of the opening portion 101 may be continuously removed. For example, the surface protection film 100 is dry-etched using a chlorine-based gas to form the opening portion 101 at the surface protection film 100, and the cap layer 110 of the opening portion 101 is removed. Alternatively, after the opening portion 101 is formed at the surface protection film 100 by a predetermined etching process, the cap layer 110 exposed through the opening portion 101 may be removed by another etching process.

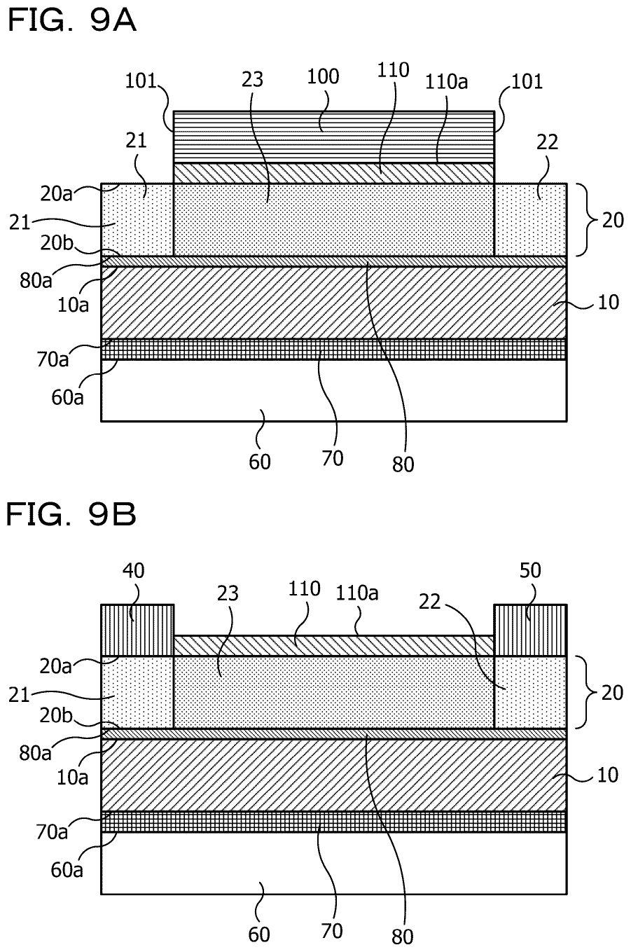

After the formation of the surface protection film 100 having the opening portion 101 and the partial removal of the cap layer 110, as illustrated in FIG. 9A, the first region 21 and the second region 22 having low In compositions are formed at the barrier layer 20 exposed from the surface protection film 100 and the cap layer 110. At the time of the formation of the first region 21 and the second region 22, in a state in which the barrier layer 20 is exposed through the surface protection film 100 and the cap layer 110, heat treatment is performed in a hydrogen atmosphere, under a temperature condition in a range of 600° C. to 800° C., for example, at a temperature of 700° C. By performing such heat treatment, In is desorbed from a region of the barrier layer 20 exposed from the surface protection film 100 and the cap layer 110. Therefore, the first region 21 and the second region 22 having the low In compositions are formed at the regions of the barrier layer 20 exposed from the surface protection film 100 and the cap layer 110. For example, by the heat treatment, the first region 21 and the second region 22 having the Al composition z of 0.40≤z<1.00 and the In composition y of 0≤x≤0.05 (meanwhile, 0.00<y+z<1.00) of In_{y}Al_{z}Ga_{1-y-z}N are formed. A region between the first region 21 and the second region 22, for example, a region in which the desorption of In is suppressed by being covered with the surface protection film 100 becomes the third region 23 having a higher In composition than the In compositions the first region 21 and the second region 22. For example, the third region 23 of In_{y}Al_{z}Ga_{1-y-z}N having an initial composition as described above is formed.

For example, the first region 21 and the second region 22 having the low In compositions are formed so as to extend from one surface 20a to the other surface 20b of the barrier layer 20, for example, so as to be in contact with the surface 80a of the spacer layer 80 (the surface 10a of the channel layer 10 in a case where the spacer layer 80 is not provided). With the formation in this manner, the barrier layer 20 between the channel layer 10, and the source electrode 40 and the drain electrode 50 formed on the first region 21 and the second region 22, respectively, as described below is occupied by the first region 21 and the second region 22 having low electric resistances by the low In composition. Therefore, it is possible to reduce a contact resistance between the channel layer 10, and the source electrode 40 and the drain electrode 50, as compared with a case where the barrier layer 20 between the channel layer 10, and the source electrode 40 and the drain electrode 50 is partially made with a low In composition, for example, only a surface layer portion has the low In composition.

After the formation of the first region 21 and the second region 22 of the barrier layer 20, the surface protection film 100 is removed. After the removal of the surface protection film 100, as illustrated in FIG. 9B, the source electrode 40 and the drain electrode 50 are formed on the first region 21 and the second region 22 formed at the barrier layer 20, respectively. At this time, first, an electrode metal is formed at each of the first region 21 at which the source electrode 40 is to be formed and the second region 22 at which the drain electrode 50 is to be formed, by using the photolithography technology, a vapor deposition technology, and a lift-off technology. For example, a stack of Ta having a thickness of 20 nm and Al having a thickness of 200 nm is formed as the electrode metal. After the formation of the electrode metal, heat treatment is performed under a temperature condition in a range of 400° C. to 1000° C., for example, at a temperature of 550° C. in a nitrogen atmosphere to build an ohmic contact of the electrode metal. Therefore, the source electrode 40 and the drain electrode 50 are formed on the first region 21 and the second region 22, respectively.

A region of the barrier layer 20 facing the source electrode 40, for example, a region immediately below the source electrode 40 is the first region 21 having the low In composition. A region of the barrier layer 20 facing the drain electrode 50, for example, a region immediately below the drain electrode is the second region 22 having the low In composition.

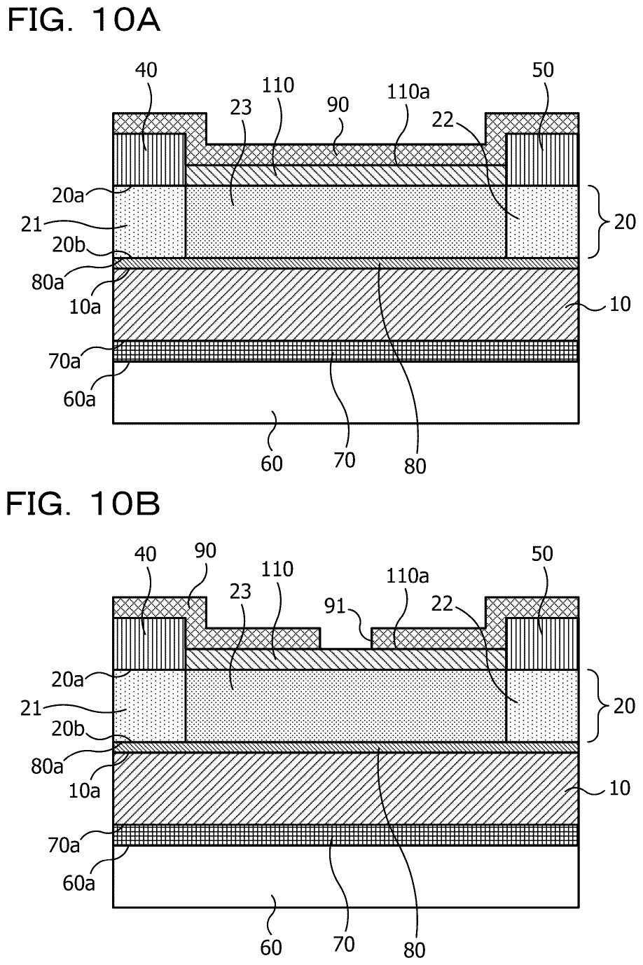

After the formation of the source electrode 40 and the drain electrode 50, as illustrated in FIG. 10A, the passivation film 90 is formed so as to cover the cap layer 110, the source electrode 40, and the drain electrode 50. For example, the passivation film 90 of SiN or the like having a film thickness in a range from 2 nm to 500 nm, for example, having a film thickness of 100 nm is formed by using the plasma CVD method. The ALD method, the sputtering method, or the like may be used to form the passivation film 90.

After the formation of the passivation film 90, as illustrated in FIG. 10B, the passivation film 90 in a region in which the gate electrode 30 is to be formed is partially removed to form the opening portion 91 leading to the cap layer 110. In this case, first, a mask (not illustrated) having an opening portion in the region where the gate electrode 30 is to be formed is formed by using the photolithography technology, and dry etching is performed. The passivation film exposed through the opening portion of the mask is removed by this etching, and the opening portion 91 of the passivation film 90 is formed. The etching of the passivation film 90 is performed by, for example, dry etching using a fluorine-based or chlorine-based gas. Alternatively, the passivation film 90 may be etched by wet etching using hydrofluoric acid, buffered hydrofluoric acid, or the like. Damage to the barrier layer 20 during the etching is suppressed by the cap layer 110. After the etching of the passivation film 90, the mask is removed.

After the formation of the opening portion 91 of the passivation film 90, as illustrated in FIG. 7 described above, the gate electrode 30 is formed at a position of the opening portion 91. In this case, an electrode metal is formed at the position of the opening portion 91 of the passivation film 90 by using the photolithography technology, the vapor deposition technology, and the lift-off technology. For example, a stack of Ni having a thickness of 30 nm and Au having a thickness of 400 nm is formed as the electrode metal. The electrode metal is formed over the upper surface of the passivation film 90, and is also formed to enter the opening portion 91. The gate electrode 30 that functions as a Schottky electrode is thereby formed.

By the steps in this manner, the semiconductor device 1B as illustrated in FIG. 7 described above is manufactured.

As described above, in the semiconductor device 1B, the first region 21 having the low In composition of the barrier layer 20 is provided immediately below the source electrode 40, and the second region 22 having the low In composition of the barrier layer 20 is provided immediately below the drain electrode 50. Therefore, in the semiconductor device 1B, a contact resistance between the source electrode 40 and the drain electrode 50, and the channel layer 10 is reduced. By reducing the contact resistance, an increase in resistance of an electron transport path formed between the source electrode 40 and the drain electrode 50 via the channel layer 10 and an increase in on-resistance of the electron transport path are suppressed. By providing the cap layer 110 that covers the barrier layer 20 in the semiconductor device 1B, damage to the barrier layer 20 is suppressed, and a leakage current or the like is suppressed. Accordingly, the high-performance semiconductor device 1B having a low contact resistance, a low on-resistance, and a high output is realized.

In the manufacturing of the semiconductor device 1B, the first region 21 and the second region 22 having the low In compositions of the barrier layer 20 are formed by desorbing In by heat treatment in a hydrogen atmosphere. Therefore, it is possible to realize the high-performance semiconductor device 1B having a low contact resistance while suppressing an increase in the number of steps as in the case where a regrowth layer formation technology is employed. It is possible to realize the high-performance semiconductor device 1B having a low contact resistance by suppressing a dependence on a crystal dislocation density of the barrier layer 20 and the channel layer 10 below the barrier layer 20, or the base substrate 60, as in the case where the pit-assisted etching technology is employed.

In the semiconductor device 1B, the types of metals and the layer structures of the gate electrode 30, the source electrode 40, and the drain electrode 50 are not limited to the examples described above, and the methods for forming the gate electrode 30, the source electrode 40, and the drain electrode 50 are not limited to the examples described above. Each of the gate electrode 30, the source electrode 40, and the drain electrode 50 may have a single-layer structure or a stack structure. At the time of the formation of the source electrode 40 and the drain electrode 50, the heat treatment as described above does not have to be performed as long as the ohmic contact is realized by the formation of the electrode metals for these electrodes. At the time of the formation of the gate electrode 30, heat treatment may be further performed after the formation of the electrode metal for the gate electrode 30.

Although an example in which the gate electrode 30 functioning as a Schottky electrode is provided in the semiconductor device 1B is described here, a gate insulating film using oxides, nitrides, oxynitrides, or the like may be provided between the gate electrode 30 and the barrier layer 20 to form an MIS type gate structure.

As described above, the first to third embodiments are described.

The semiconductor device 1, 1A, 1B, and the like having the configurations described in the first to third embodiments described above may be applied to various electronic devices. As an example, description is given below of the cases where the semiconductor devices having the configurations as described above are applied to a semiconductor package, a power factor correction circuit, a power supply device, and an amplifier.

### Fourth Embodiment

An example of applying the semiconductor device having the configuration as described above to a semiconductor package is described here, as a fourth embodiment.

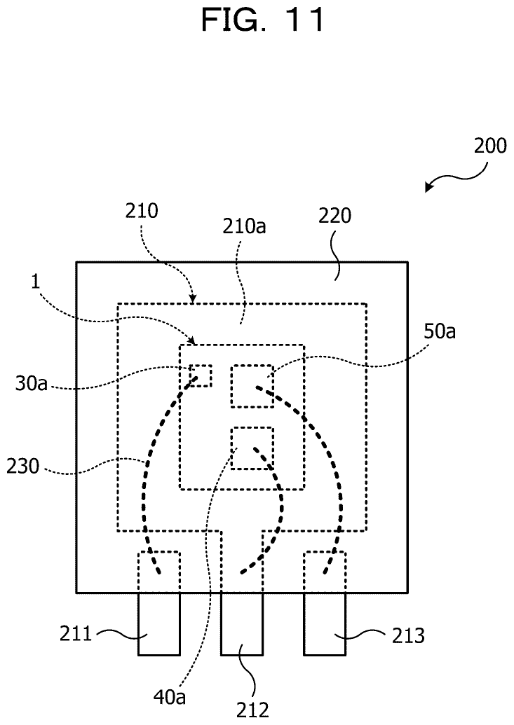

FIG. 11 is a diagram describing an example of a semiconductor package according to the fourth embodiment. FIG. 11 schematically illustrates a main portion plan view of the example of the semiconductor package.

A semiconductor package 200 illustrated in FIG. 11 is an example of a discrete package. For example, the semiconductor package 200 includes the semiconductor device 1 (FIG. 1) described in the first embodiment described above, a lead frame 210 over which the semiconductor device 1 is mounted, and a resin 220 that seals the semiconductor device 1 and the lead frame 210.

For example, the semiconductor device 1 is mounted over a die pad 210a of the lead frame 210 by using a die-attach material or the like (not illustrated). A pad 30a coupled to the gate electrode 30 described above, a pad coupled to the source electrode 40, and a pad 50a coupled to the drain electrode 50 are provided in the semiconductor device 1. The pad 30a, the pad and the pad 50a are coupled to a gate lead 211, a source lead 212, and a drain lead 213 of the lead frame 210, respectively, by using wires 230 made of Au, Al, and the like. The lead frame 210, the semiconductor device 1 mounted over the lead frame 210, and the wires 230 coupling the lead frame 210 and the semiconductor device 1 to each other are sealed in the resin 220 such that each of the gate lead 211, the source lead 212, and the drain lead 213 is partially exposed.

An external coupling electrode coupled to the source electrode 40 may be provided over a surface of the semiconductor device 1 on the opposite side to a surface at which the pad 30a coupled to the gate electrode 30 and the pad 50a coupled to the drain electrode 50 are provided. A conductive joining material such as solder may be used to couple the external coupling electrode to the die pad 210a leading to the source lead 212.

For example, the semiconductor device 1 described in the first embodiment described above is used, and the semiconductor package 200 having such a configuration is obtained.

As described above, in the semiconductor device 1, the first region 21 and the second region 22 having the low In compositions are provided immediately below the source electrode 40 and the drain electrode 50, respectively, which are provided over the barrier layer 20 in which a nitride semiconductor containing In, Al, and Ga is used. The first region 21 and the second region 22 having the low In compositions has a lower electric resistance than an electric resistance of the third region 23 which is located between the first region 21 and the second region 22 and has a higher In composition than the first region 21 and the second region 22. Accordingly, a contact resistance between the source electrode 40 and the drain electrode 50, and the channel layer 10 provided under the barrier layer 20 is reduced. Therefore, the high-performance semiconductor device 1 having a low contact resistance, a low on-resistance, and a high output is realized. The high-performance semiconductor package 200 is realized by using such a semiconductor device 1.

Although the semiconductor device 1 is described here as an example, a semiconductor package may be obtained in the same manner by using the other semiconductor devices 1A, 1B, and the like.

### Fifth Embodiment

An example of applying the semiconductor device having the configuration as described above to a power factor correction circuit is described here, as a fifth embodiment.

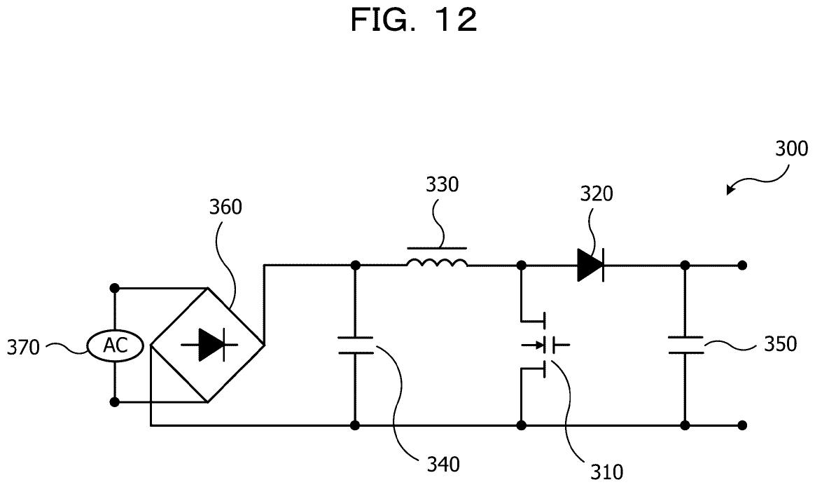

FIG. 12 is a diagram describing an example of a power factor correction circuit according to the fifth embodiment. FIG. 12 illustrates an equivalent circuit diagram of the example of the power factor correction circuit.

A power factor correction (PFC) circuit 300 illustrated in FIG. 12 includes a switch element 310, a diode 320, a choke coil 330, a capacitor 340, a capacitor 350, a diode bridge 360, and an alternating current (AC) power supply 370.

In the PFC circuit 300, a drain electrode of the switch element 310 is coupled to an anode terminal of the diode 320 and one terminal of the choke coil 330. A source electrode of the switch element 310 is coupled to one terminal of the capacitor 340 and one terminal of the capacitor 350. Another terminal of the capacitor 340 is coupled to another terminal of the choke coil 330. Another terminal of the capacitor 350 is coupled to a cathode terminal of the diode 320. A gate driver is coupled to a gate electrode of the switch element 310. The alternating current power supply 370 is coupled between both terminals of the capacitor 340 via the diode bridge 360, and a direct current (DC) power supply is extracted from between both terminals of the capacitor 350.

For example, the semiconductor devices 1, 1A, 1B, and the like described above are used for the switch element 310 of the PFC circuit 300 having such a configuration.

As described above, in the semiconductor devices 1, 1A, 1B, and the like, the first region 21 and the second region 22 having the low In compositions are provided immediately below the source electrode 40 and the drain electrode 50, respectively, which are provided over the barrier layer 20 in which a nitride semiconductor containing In, Al, and Ga is used. The first region 21 and the second region 22 having the low In compositions has a lower electric resistance than an electric resistance of the third region 23 which is located between the first region 21 and the second region 22 and has a higher In composition than the first region 21 and the second region 22. Accordingly, a contact resistance between the source electrode 40 and the drain electrode 50, and the channel layer 10 provided under the barrier layer 20 is reduced. Therefore, the high-performance semiconductor devices 1, 1A, 1B, and the like having a low contact resistance, a low on-resistance, and a high output are realized. The high-performance PFC circuit 300 is realized by using such semiconductor devices 1, 1A, 1B, and the like.

### Sixth Embodiment

An example of applying the semiconductor device having the configuration as described above to a power supply device is described here, as a sixth embodiment.

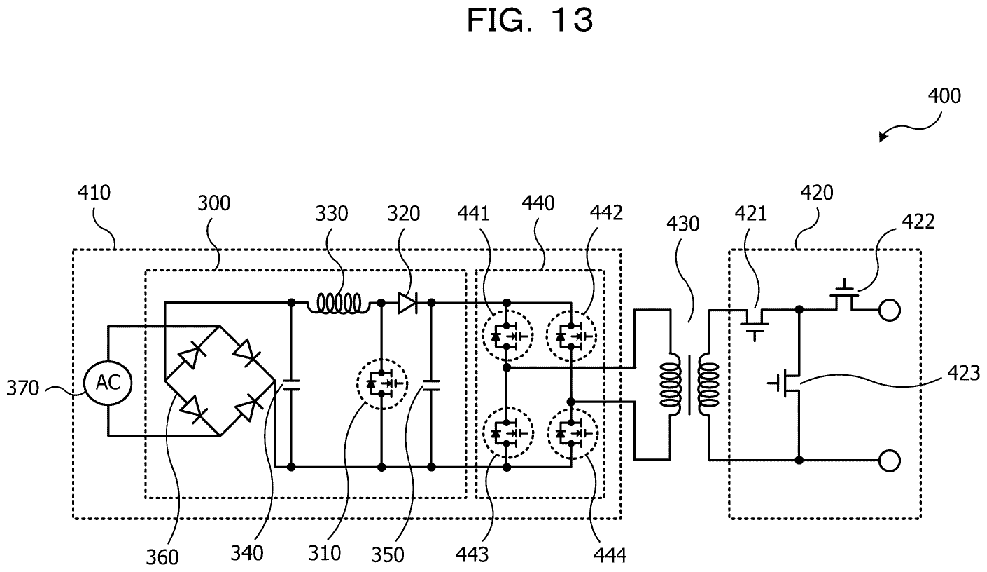

FIG. 13 is a diagram describing an example of a power supply device according to the sixth embodiment. FIG. 13 illustrates an equivalent circuit diagram of the example of the power supply device.

A power supply device 400 illustrated in FIG. 13 includes a primary-side circuit 410, a secondary-side circuit 420, and a transformer 430 provided between the primary-side circuit 410 and the secondary-side circuit 420.

The primary-side circuit 410 includes the PFC circuit 300 as described in the fifth embodiment described above and an inverter circuit, for example, a full-bridge inverter circuit 440 coupled between both terminals of the capacitor 350 of the PFC circuit 300. The full-bridge inverter circuit 440 includes a plurality of (for example, four in this case) switch elements of a switch element 441, a switch element 442, a switch element 443, and a switch element 444.

The secondary-side circuit 420 includes a plurality of (for example, three in this case) switch elements of a switch element 421, a switch element 422, and a switch element 423.

For example, the semiconductor devices 1, 1A, 1B, and the like described above are used for the switch element 310 of the PFC circuit 300 included in the primary-side circuit 410 and the switch elements 441 to 444 of the full-bridge inverter circuit 440 in the power supply device 400 having such a configuration. For example, a normal MIS type field-effect transistor using Si is used for the switch elements 421 to 423 of the secondary-side circuit 420 in the power supply device 400.

As described above, in the semiconductor devices 1, 1A, 1B, and the like, the first region 21 and the second region 22 having the low In compositions are provided immediately below the source electrode 40 and the drain electrode 50, respectively, which are provided over the barrier layer 20 in which a nitride semiconductor containing In, Al, and Ga is used. The first region 21 and the second region 22 having the low In compositions has a lower electric resistance than an electric resistance of the third region 23 which is located between the first region 21 and the second region 22 and has a higher In composition than the first region 21 and the second region 22. Accordingly, a contact resistance between the source electrode 40 and the drain electrode 50, and the channel layer 10 provided under the barrier layer 20 is reduced. Therefore, the high-performance semiconductor devices 1, 1A, 1B, and the like having a low contact resistance, a low on-resistance, and a high output are realized. The high-performance power supply device 400 is realized by using such semiconductor devices 1, 1A, 1B, and the like.

### Seventh Embodiment

An example of applying the semiconductor device having the configuration as described above to an amplifier is described here, as a seventh embodiment.

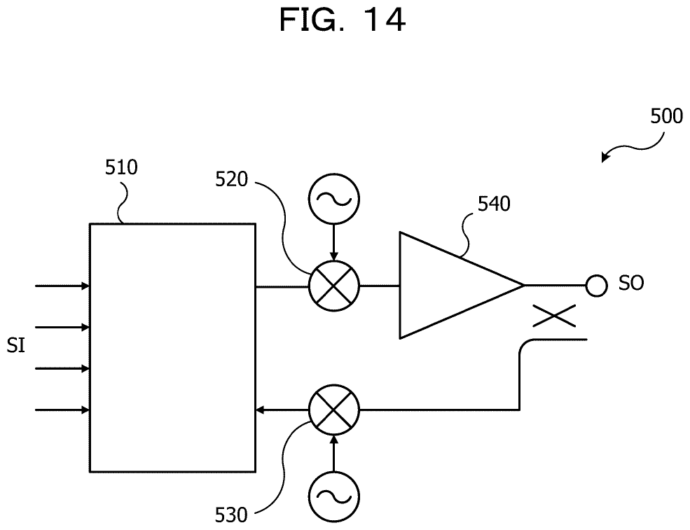

FIG. 14 is a diagram describing an example of an amplifier according to the seventh embodiment. FIG. 14 illustrates an equivalent circuit diagram of the example of the amplifier.

An amplifier 500 illustrated in FIG. 14 includes a digital predistortion circuit 510, a mixer 520, a mixer 530, and a power amplifier 540.

The digital predistortion circuit 510 compensates for non-linear distortion of an input signal. The mixer 520 mixes an alternating current signal and an input signal SI subjected to the non-linear distortion compensation. The power amplifier 540 amplifies a signal obtained by mixing the alternating current signal and the input signal SI. For example, in the amplifier 500, switching of a switch may cause an output signal SO to be mixed with an alternating current signal in the mixer 530 and to be transmitted to the digital predistortion circuit 510. The amplifier 500 may be used as a high-frequency amplifier or a high-output amplifier.

As the power amplifier 540 of the amplifier 500 having such a configuration, the semiconductor devices 1, 1A, 1B, and the like described above are used.

As described above, in the semiconductor devices 1, 1A, 1B, and the like, the first region 21 and the second region 22 having the low In compositions are provided immediately below the source electrode 40 and the drain electrode 50, respectively, which are provided over the barrier layer 20 in which a nitride semiconductor containing In, Al, and Ga is used. The first region 21 and the second region 22 having the low In compositions has a lower electric resistance than an electric resistance of the third region 23 which is located between the first region 21 and the second region 22 and has a higher In composition than the first region 21 and the second region 22. Accordingly, a contact resistance between the source electrode 40 and the drain electrode 50, and the channel layer 10 provided under the barrier layer 20 is reduced. Therefore, the high-performance semiconductor devices 1, 1A, 1B, and the like having a low contact resistance, a low on-resistance, and a high output are realized. The high-performance amplifier 500 is realized by using such semiconductor devices 1, 1A, 1B, and the like.

Various electronic devices (the semiconductor package 200, the PFC circuit 300, the power supply device 400, the amplifier 500, and the like described in the fourth to seventh embodiments described above) to which the semiconductor devices 1, 1A, 1B, and the like described above are applied may be mounted in various electronic apparatuses (may also be referred to as “electronic devices”). For example, the electronic devices may be mounted in various electronic apparatuses such as a computer (a personal computer, a super computer, a server, or the like), a smartphone, a mobile phone, a tablet terminal, a sensor, a camera, an audio device, a measurement device, an inspection device, a manufacturing device, a transmitter, a receiver, and a radar device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a channel layer that includes a first nitride semiconductor that contains Ga;
a barrier layer that is provided on a first surface side of the channel layer, and includes a second nitride semiconductor that contains In, Al, and Ga;
a source electrode and a drain electrode that are provided on a second surface side of the barrier layer opposite to the channel layer side; and
a gate electrode that is provided between the source electrode and the drain electrode, on the second surface side of the barrier layer,
wherein an In composition of each of a first region of the barrier layer that faces the source electrode and a second region of the barrier layer that faces the drain electrode is smaller than an In composition of a third region between the first region and the second region of the barrier layer.

2. The semiconductor device according to claim 1,
wherein the first region and the second region of the barrier layer extend from the second surface of the barrier layer to a third surface opposite to the second surface.

3. The semiconductor device according to claim 1,
wherein an Al composition of each of the first region and the second region of the barrier layer is equal to or more than 0.40.

4. The semiconductor device according to claim 1,
wherein the In composition of each of the first region and the second region of the barrier layer is equal to or less than 0.05.

5. The semiconductor device according to claim 1, further comprising:
a spacer layer that includes a third nitride semiconductor that contains Al between the channel layer and the barrier layer.

6. The semiconductor device according to claim 1, further comprising:
a cap layer that is provided on the second surface side of the barrier layer between the source electrode and the drain electrode and includes a fourth nitride semiconductor that contains Ga,
wherein the gate electrode is provided on the second surface side of the barrier layer via the cap layer.

7. A method for manufacturing a semiconductor device, comprising:
forming a barrier layer that includes a second nitride semiconductor that contains In, Al, and Ga on a first surface side of a channel layer that includes a first nitride semiconductor that contains Ga;
forming a source electrode and a drain electrode on a second surface side of the barrier layer opposite to the channel layer side; and
forming a gate electrode between the source electrode and the drain electrode, on the second surface side of the barrier layer,
wherein the forming of the barrier layer includes setting an In composition of each of a first region of the barrier layer that faces the source electrode and a second region of the barrier layer that faces the drain electrode to be smaller than an In composition of a third region between the first region and the second region of the barrier layer.

8. The method for manufacturing the semiconductor device according to claim 7,
wherein the forming of the barrier layer includes forming the first region and the second region that have the In composition smaller than the In composition of the third region by performing heat treatment in a hydrogen atmosphere, in a state in which a region where the third region is to be formed is covered with a protection film and regions where the first region and the second region are to be formed are exposed.

9. An electronic device comprising:
a channel layer that includes a first nitride semiconductor that contains Ga;
a barrier layer that is provided on a first surface side of the channel layer, and includes a second nitride semiconductor that contains In, Al, and Ga;
a source electrode and a drain electrode that are provided on a second surface side of the barrier layer opposite to the channel layer side; and
a gate electrode that is provided between the source electrode and the drain electrode, on the second surface side of the barrier layer,
wherein an In composition of each of a first region of the barrier layer that faces the source electrode and a second region of the barrier layer that faces the drain electrode is smaller than an In composition of a third region between the first region and the second region of the barrier layer.
